(19) United States
(12) Patent Application Publication
(10) Pub. No.: US 2012/0195117 A1
(43) Pub. Date: Aug. 2, 2012

(54) SEMICONDUCTOR SYSTEM AND DATA PROGRAMMING METHOD

(75) Inventor: Jung Chul HAN, Icheon-si (KR)

(73) Assignee: HYNIX SEMICONDUCTOR INC., Icheon-si (KR)

(21) Appl. No.: 13/219,628

(22) Filed: Aug. 27, 2011

(30) Foreign Application Priority Data
Jan. 27, 2011 (KR) 10-2011-0008306

(51) Int. Cl. G11C 16/10; G11C 16/06

(52) U.S. Cl. 365/185.03; 365/185.09

(57) ABSTRACT

A data programming method includes the steps of determining whether a threshold voltage distribution of a memory cell, where a first bit value of writing data was programmed, has deviated from a targeted first voltage range, correcting the first bit value through an error correction code if the threshold voltage distribution of the memory cell has deviated from the first voltage range, and programming a corrected first bit value and a second bit value of the writing data to the memory cell.

### CROSS-REFERENCES TO RELATED APPLICATION

The present application claims priority under 35 U.S.C. §119(a) to Korean application number 10-2011-0008306, filed on Jan. 27, 2011, in the Korean Intellectual Property Office, which is incorporated herein by reference in its entirety as set forth in full.

### BACKGROUND

1. Technical Field

The present invention relates to a semiconductor system, and more particularly, to a data programming technology.

2. Related Art

A flash memory apparatus, which is a representative example of a non-volatile memory apparatus, includes a non-volatile memory cell array. Each non-volatile memory cell includes a transistor having a control gate and a floating gate.

Meanwhile, when a programming voltage is applied to a control gate of the memory cell, tunneling phenomenon occurs at a tunneling oxide, and electric charges move into the floating gate. When an erase voltage is applied to the substrate of the memory cell, the tunneling phenomenon occurs at the tunneling oxide, and the electric charges move out of the floating gate. Here, the programming voltage is transferred to the memory cell through word lines.

FIG. 1 is a diagram illustrating threshold voltage distributions of a single-level cell (SLC) and a multi-level cell (MLC).

FIG. 1 illustrates a threshold voltage distribution 11 of the single-level cell, a threshold voltage distribution 12 of the multi-level cell used to store 2-bit data, and a threshold voltage distribution 13 of the multi-level cell used to store 3-bit data.

The single-level cell used to store 1-bit data has two threshold voltage distributions. The multi-level cell used to store 2-bit data has four threshold voltage distributions. The multi-level cell used to store 3-bit data has eight threshold voltage distributions. Threshold voltage distributions L0 at the lowest level are formed when an erase operation is performed. Here, the threshold voltage distribution may be called a data distribution and is similar to a Gaussian distribution. The multi-level cell used to store 3-bit data may also be called a triple-level cell. Hereinafter, a memory cell used to store data of 2 bits or more will be generally called a multi-level cell.

The multi-level cell forms a plurality of threshold voltages through a plurality of programming operations. As the programming operation is performed, that is, a programming voltage is repeatedly applied, the level of a threshold voltage of the memory cell increases. For example, the multi-level cell used to store 2-bit data has four threshold voltages L0 to L3. Among the four threshold voltages L0 to L3, the first threshold voltage L0 which has lowest threshold voltage is formed when the erase operation is performed. The second to fourth threshold voltages L1 to L3 are formed by a plurality of programming operations.

FIG. 2 is a diagram illustrating a change in the threshold voltage distribution of the memory cell.

FIG. 2 illustrates an increase in the range of the threshold voltage distribution of the memory cell after the erase operation and the programming operation are performed. That is, the threshold voltage Vth of the memory cell is determined by the amount of charges stored in the floating gate, and charge loss occurs as a certain time lapses. For example, when the charge loss occurs, the level of the threshold voltage L0 having a negative threshold voltage level rises, and the levels of the threshold voltages L1 to L3 having a positive threshold voltage level drops. As a result, the range of the threshold voltage distribution of the memory cell is widened, and adjacent threshold voltage distributions may overlap each other in significant charge loss. Further, because a verifying operation is performed after a programming operation to determine a completion of a programming based on the current threshold voltage Vth, if the threshold voltage is excessively shifted due to charge loss, the completion of the programming may be erroneously determined, and thus a failure may occur.

### SUMMARY

A data programming method and a semiconductor system, which can improve the reliability of a data programming operation even if charge loss occurs, are described herein.

In an exemplary embodiment of the present invention, a data programming method includes the steps of determining whether a threshold voltage of a memory cell, where a first bit value of writing data was programmed, has deviated from a targeted first voltage range, correcting the first bit value through an error correction code if the threshold voltage of the memory cell has deviated from the first voltage range, and programming a corrected first bit value and a second bit value of the writing data to the memory cell.

In another exemplary embodiment of the present invention, a data programming method includes the steps of determining whether threshold voltage distributions of a plurality of memory cells, where first bit values of writing data were programmed, have deviated from a targeted first voltage range, correcting the first bit value through an error correction code if the threshold voltage distributions of the plurality of memory cells have deviated from the first voltage range, and programming a corrected first bit value and a second bit value of the writing data to the plurality of memory cells.

In another exemplary embodiment of the present invention, a semiconductor memory apparatus includes a controller configured to determine whether threshold voltage distributions of the plurality of memory cells, where a first bit value of writing data was programmed, have deviated from a targeted first voltage range, correct the first bit value through an error correction code if the threshold voltage distributions of the plurality of memory cells have deviated from the first voltage range, and program a corrected first bit value and a second bit value of the writing data to the plurality of memory cells.

In another exemplary embodiment of the present invention, a semiconductor system includes a semiconductor memory apparatus configured to program a first bit value of writing data to a plurality of memory cells in response to a first writing command and program a corrected first bit value and a second bit value of the writing data to the plurality of memory cells in response to a second writing command, and a controller configured to determine whether threshold voltage distributions of the plurality of memory cells, where a first bit value of the writing data was programmed, have deviated from a targeted first voltage range when providing the first writing command, the second writing command and the wiring data to the semiconductor memory apparatus, correct the first bit value through an error correction code if the threshold voltage distributions of the plurality of memory cells have deviated from the first voltage range, and input a corrected first bit value, a second bit value of the writing data, and the second writing command to the semiconductor memory apparatus.

### BRIEF DESCRIPTION OF THE DRAWINGS

Features, aspects, and embodiments are described in conjunction with the attached drawings, in which:

FIG. 1 is a diagram illustrating threshold voltage distributions of a single-level cell and a multi-level cell;

FIG. 2 is a diagram illustrating a change in a threshold voltage distribution of a memory cell;

FIG. 3 is a configuration diagram of a semiconductor system according to an exemplary embodiment of the present invention;

FIG. 4 is a configuration diagram of a semiconductor memory apparatus according to another exemplary embodiment of the present invention; and

FIG. 5 is a flowchart illustrating a data programming method according to another exemplary embodiment of the present invention.

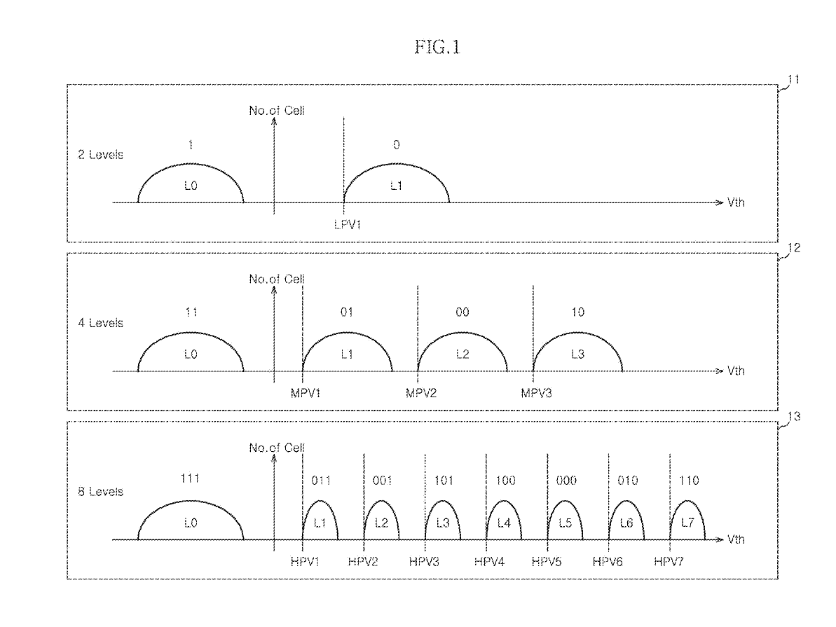

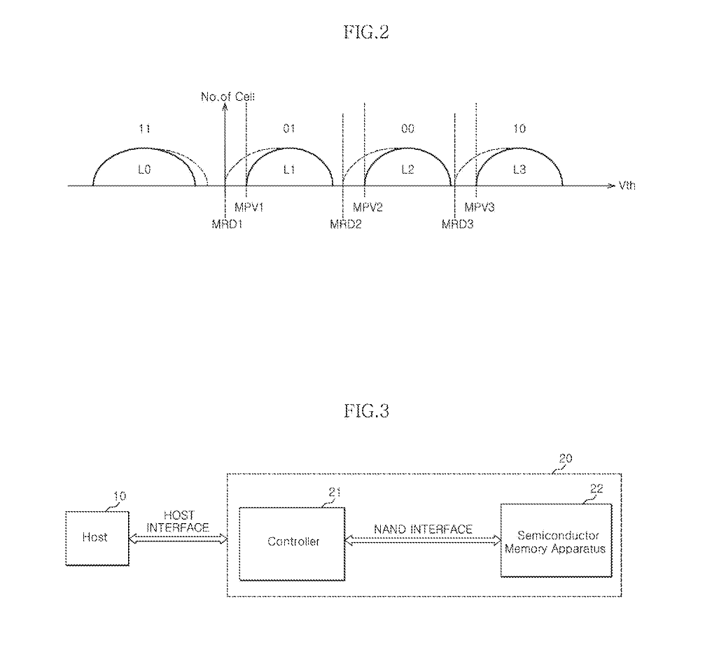

### DETAILED DESCRIPTION

Hereinafter, embodiments of the present invention will be described in detail with reference to the accompanying drawings such that the scope of the present invention can be easily embodied by those skilled in the art.

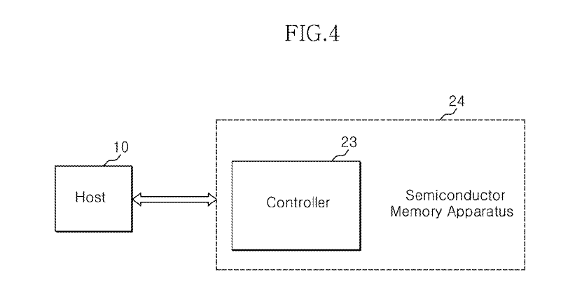

FIG. 3 is a configuration diagram of a semiconductor system according to an exemplary embodiment of the present invention.

Referring to FIG. 3, a semiconductor system 20 includes a controller 21 and a semiconductor memory apparatus 22. It is assumed that the semiconductor memory apparatus 22 is a NAND flash memory apparatus.

A host 10 may be defined as an application such as a SD, a MMC or a USB, and is configured to generally manage the semiconductor system 20. The host 10 and the semiconductor system 20 exchange signals through a host interface. The controller 21 and the semiconductor memory apparatus 22 exchange signals through a NAND interface. The interface includes an address channel, a command channel, a data channel and the like. Although the controller 21 is separated from the semiconductor memory apparatus 22 in this exemplary embodiment, the controller 21 may be arranged in the semiconductor memory apparatus 22.

The semiconductor system 20 configured as mentioned above will be described in more detail below.

The semiconductor memory apparatus 22 includes a plurality of memory cells. In the exemplary embodiment, it is assumed that each memory cell includes a transistor having a control gate and a floating gate. That is, the memory cell includes a NAND flash memory cell. In the exemplary embodiment, it is assumed that the memory cell is a multi-level cell (MLC) for storing multiple bits. For example, a memory cell used to store 2-bit data may store a first bit value and a second bit value. A memory cell used to store 3-bit data may store a first bit value, a second bit value and a third bit value. A multi-level cell used to store 3-bit data may be called a triple-level cell (TLC). In the exemplary embodiment, a memory cell used to store data of 2 bits or more will be generally called a multi-level cell.

The controller 21 determines whether threshold voltage distributions of a plurality of memory cells, where a first bit value of writing data was programmed, have deviated from a targeted first voltage range. When the threshold voltage distributions of the plurality of memory cells have deviated from the first voltage range, the controller 21 corrects the first bit value through an error correction code (ECC). The controller 21 controls the corrected first bit value and a second bit value of the writing data to be programmed to the plurality of memory cells.

In the exemplary embodiment, the first bit value and second bit value indicate each bit value of multi-bit data. For example, when it is assumed that a first bit value of 3-bit data indicates the least significant bit, a second bit value may be defined to indicate one of an intermediate significant bit and the most significant bit. In another example, when it is assumed that a first bit value of 3-bit data indicates an intermediate significant bit, a second bit value may be defined to indicate the most significant bit. That is, the second bit value may be defined as a bit value relatively higher than the first bit value.

The semiconductor memory apparatus 22 is configured to program the first bit value of the writing data to the plurality of memory cells in response to a first writing command and to program the corrected first bit value and the second bit value of the writing data to the plurality of memory cells in response to a second writing command.

According to an example, the first writing command and the second writing command have command sequences different from each other. The operation according to the command sequence is determined by a plurality of unit command codes sequentially applied during a plurality of command cycles. In this regard, the first writing command is distinguished from the second writing command by the plurality of unit command codes different from each other.

The controller 21 is configured to provide the semiconductor memory apparatus 22 with the first writing command, the second writing command, and the writing data, and to determine whether the threshold voltage distributions of the plurality of memory cells, where the first bit value of the writing data was programmed, have deviated from the targeted first voltage range. If the threshold voltage distributions of the plurality of memory cells have deviated from the first voltage range, the controller 21 corrects the first bit value through the error correction code, and provides the semiconductor memory apparatus 22 with the corrected first bit value, the second bit value of the writing data, and the second writing command.

Meanwhile, if the threshold voltage distributions of the plurality of memory cells have not deviated from the first voltage range, the controller 21 provides the semiconductor memory apparatus 22 with the second bit value of the writing data and the first writing command.

FIG. 4 is a configuration diagram of a semiconductor memory apparatus according to another exemplary embodiment of the present invention.

Referring to FIG. 4, a semiconductor memory apparatus 24 includes a controller 23. The controller 23 determines whether threshold voltage distributions of the plurality of memory cells, where a first bit value of writing data was programmed, have deviated from a targeted first voltage range, corrects the first bit value through an error correction code if the threshold voltage distributions of the plurality of memory cells have deviated from the first voltage range, and programs a corrected first bit value and a second bit value of the writing data to the plurality of memory cells.

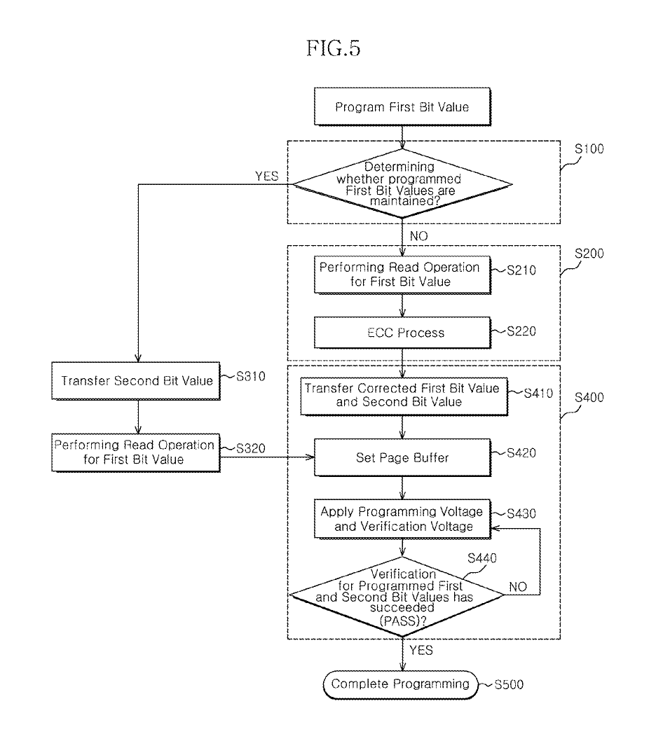

FIG. 5 is a flowchart illustrating a data programming method according to another exemplary embodiment of the present invention.

The data programming method of the semiconductor system according to this exemplary embodiment will be described in detail with reference to FIG. 4 below.

The data programming method includes a step (S100) of determining whether programmed first bit values are maintained, a step (S200) of correcting the first bit value through the error correction code if the threshold voltage distributions of the plurality of memory cells have deviated from the first voltage range, and a step (S400) of programming the corrected first bit value and the second bit value of the writing data to the plurality of memory cells.

The step (S100) of determining whether programmed first bit values are maintained includes determining whether the threshold voltage distributions of the plurality of memory cells, where the first bit value of the writing data was programmed, have deviated from the targeted first voltage range. Here, the targeted first voltage range is the range of the threshold voltage of the plurality of memory cells where the first bit value of the writing data was correctly programmed. The step of determining whether the threshold voltage of the memory cell has deviated from the first voltage range may comprise reading the first bit value from the memory cell, and determining whether the first bit value read from the memory cell is different from a targeted first bit value. Also, the step of determining whether the threshold voltage of the memory cell has deviated from the first voltage range may comprise reading the first bit value from the plurality of memory cells, and determining whether the number of the memory cell, which the first bit value read from is different from the targeted first bit value, exceeds a predetermined number. It is assumed that the memory cell is a multi-level cell used to store 3-bit data, and it is defined that an intermediate significant bit corresponds to the first bit value and the most significant bit corresponds to the second bit value when the least significant bit has been normally programmed.

The step (S200) of correcting the first bit value includes a step (S210) of performing a read operation with respect to the plurality of memory cells where the first bit value has been programmed, and a step (S220) of generating the corrected first bit value using the error correction code.

The step (S400) of programming the values to the plurality of memory cells includes a step (S410) of transferring the corrected first bit value and the second bit value, a step (S420) of setting a page buffer according to both the corrected first bit value and the second bit value, and steps (S430 and S440) of applying a programming voltage pulse and a programming verification voltage pulse to the plurality of memory cells until the programming is completed. Here, the writing data is programmed to the memory cells through an incremental step pulse programming (ISPP) operation. According to the ISPP operation, a programming state is repeatedly checked by applying the programming verification voltage pulse to the memory cells after applying the programming voltage pulse to the memory cells. Such an operation is repeated until the plurality of memory cells have desired programming level distributions, that is, desired threshold voltage distributions.

Meanwhile, if the threshold voltage distributions of the plurality of memory cells are maintained in the step (S100) of determining whether programmed first bit values are maintained, the data programming operation is performed through a step (S310) of transferring the second bit value, a step (S320) of performing a read operation with respect to the plurality of memory cells where the first bit value has been programmed, the step (S420) of setting the page buffer according to the second bit value, and the steps (S430 and S440) of applying the programming voltage pulse and the programming verification voltage pulse to the plurality of memory cells until the programming is completed.

The reason for performing the step (S320) of performing the read operation with respect to the plurality of memory cells with the programmed first bit value is because the threshold voltages of the memory cells based on the second bit value are determined according to the first bit value.

In the semiconductor system and the data programming method as described above, when multi-bit data is stored in a multi-level cell, if a threshold voltage Vth is significantly shifted due to great charge loss of the first bit value, the first bit value is corrected using the error correction code and then the corrected first bit value and the second bit value are programmed. Consequently, even if great charge loss occurs, the programming operation can be reliably performed, resulting in a reduction in the number of error bits.

While certain embodiments have been described above, it will be understood to those skilled in the art that the embodiments described are by way of example only. Accordingly, the semiconductor system, and the data programming method described herein should not be limited based on the described embodiments. Rather, the semiconductor system and the data programming method described herein should only be limited in light of the claims that follow when taken in conjunction with the above description and accompanying drawings.

What is claimed is:

1. A data programming method comprising the steps of:
determining whether a threshold voltage of a memory cell, where a first bit value of writing data was programmed, has deviated from a targeted first voltage range;
correcting the first bit value through an error correction code if the threshold voltage of the memory cell has deviated from the first voltage range; and
programming a corrected first bit value and a second bit value of the writing data to the memory cell.

2. The data programming method according to claim 1, wherein the memory cell includes a transistor having a control gate and a floating gate.

3. The data programming method according to claim 1, wherein the memory cell includes a multi-level cell for storing multiple bits.

4. The data programming method according to claim 1, wherein the step of determining whether the threshold voltage of the memory cell has deviated from the first voltage range comprises the steps of:
reading the first bit value from the memory cell; and
determining whether the first bit value read from the memory cell is different from a targeted first bit value.

5. The data programming method according to claim 1, wherein the step of correcting the first bit value comprises the steps of:
performing a read operation with respect to the memory cell where the first bit value has been programmed; and
generating a corrected first bit value.

6. The data programming method according to claim 1, wherein the step of programming the corrected first bit value and the second bit value of the writing data to the memory cell comprises the steps of:
inputting the corrected first bit value and the second bit value to a page buffer; and
applying a programming voltage pulse and a programming verification voltage pulse to the memory cell until programming is completed.

7. A data programming method comprising the steps of:
determining whether threshold voltage distributions of a plurality of memory cells, where first bit values of writing data were programmed, have deviated from a targeted first voltage range;
correcting the first bit values through an error correction code if the threshold voltage distributions of the plurality of memory cells have deviated from the first voltage range; and
programming a corrected first bit value and a second bit value of the writing data to the plurality of memory cells.

8. The data programming method according to claim 7, wherein each memory cell includes a transistor having a control gate and a floating gate.

9. The data programming method according to claim 7, wherein each memory cell includes a multi-level cell for storing multiple bits.

10. The data programming method according to claim 7, wherein the step of determining whether the threshold voltage distributions of the plurality of memory cells have deviated from the first voltage range comprises the steps of:
reading the first bit value from the plurality of memory cells; and
determining whether the number of the memory cell, which the first bit value read from is different from the targeted first bit value, exceeds a predetermined number.

11. The data programming method according to claim 7, wherein the step of correcting the first bit value comprises the steps of:
performing a read operation with respect to the plurality of memory cells where the first bit value has been programmed; and
generating a corrected first bit value.

12. The data programming method according to claim 7, wherein the step of programming the corrected first bit value and the second bit value of the writing data to the plurality of memory cells comprises the steps of:
inputting the corrected first bit value and the second bit value to a page buffer; and
applying a programming voltage pulse and a programming verification voltage pulse to the plurality of memory cells until programming is completed.

13. A semiconductor memory apparatus comprising:
a controller configured to determine whether threshold voltage distributions of the plurality of memory cells, where a first bit value of writing data was programmed, have deviated from a targeted first voltage range, correct the first bit value through an error correction code if the threshold voltage distributions of the plurality of memory cells have deviated from the first voltage range, and program a corrected first bit value and a second bit value of the writing data to the plurality of memory cells.

14. The semiconductor memory apparatus according to claim 13, wherein each memory cell includes a transistor having a control gate and a floating gate.

15. The semiconductor memory apparatus according to claim 13, wherein each memory cell includes a multi-level cell for storing multiple bits.

16. A semiconductor system comprising:
a semiconductor memory apparatus configured to program a first bit value of writing data to a plurality of memory cells in response to a first writing command and program a corrected first bit value and a second bit value of the writing data to the plurality of memory cells in response to a second writing command; and
a controller configured to determine whether threshold voltage distributions of the plurality of memory cells, where a first bit value of the writing data was programmed, have deviated from a targeted first voltage range when providing the first writing command, the second writing command and the wiring data to the semiconductor memory apparatus, correct the first bit value through an error correction code if the threshold voltage distributions of the plurality of memory cells have deviated from the first voltage range, and input a corrected first bit value, a second bit value of the writing data, and the second writing command to the semiconductor memory apparatus.

17. The semiconductor system according to claim 16, wherein the first writing command and the second writing command have command sequences different from each other.

18. The semiconductor system according to claim 16, wherein the controller provides the second bit value of the writing data and the first writing command to the semiconductor memory apparatus if the threshold voltage distributions of the plurality of memory cells have not deviated from the first voltage range.

19. The semiconductor system according to claim 16, wherein each memory cell includes a transistor having a control gate and a floating gate.

20. The semiconductor system according to claim 16, wherein each memory cell includes a multi-level cell for storing multiple bits.
